(19) United States
(12) Patent Application Publication
(10) Pub. No.: US 2019/0207057 A1
(43) Pub. Date: Jul. 4, 2019

(54) METHOD OF MANUFACTURING SEMICONDUCTOR LIGHT EMITTING DEVICE

(71) Applicant: Samsung Electronics Co., Ltd, Suwon-si (KR)

(72) Inventors: Sam Mook Kang, Hwaseong-si (KR); Joo Sung Kim, Seongnam-si (KR); Jong Uk Seo, Hwaseong-si (KR); Young Jo Tak, Seongnam-si (KR)

(73) Assignee: Samsung Electronics Co., Ltd, Suwon-si (KR)

(21) Appl. No.: 16/032,222

(22) Filed: Jul. 11, 2018

(30) Foreign Application Priority Data
Dec. 28, 2017 (KR) 10-2017-0181752

(51) Int. Cl. H01L 33/00; H01L 33/12

(52) U.S. Cl. CPC H01L 33/0095; H01L 33/22; H01L 33/12; H01L 33/007

(57) ABSTRACT

A method of manufacturing a semiconductor light emitting device may include: forming a buffer layer on a substrate; forming a protective layer on the buffer layer; performing heat treatment on a stacked structure of the substrate, the buffer layer, and the protective layer; removing the protective layer; and forming a light emitting structure on the buffer layer.

### CROSS-REFERENCE TO RELATED APPLICATION(S)

This application claims benefit of priority to Korean Patent Application No. 10-2017-0181752 filed on Dec. 28, 2017 in the Korean Intellectual Property Office, the disclosure of which is incorporated herein by reference in its entirety.

### BACKGROUND

### 1. Field

Example embodiments of the present inventive concepts relate to a method of manufacturing a semiconductor light emitting device and/or a semiconductor light emitting device.

### 2. Description of Related Art

Semiconductor light emitting devices may emit light using the principle of the recombination of electrons and holes when an electric current is applied thereto, and have been widely used as light sources due to various advantages thereof such as low power consumption, high brightness, and ease of miniaturization. Further, after the development of nitride-based semiconductor light emitting devices, the utilization range thereof has been further enlarged, and such nitride-based semiconductor light emitting devices have been employed in backlight units, household lighting devices, lighting apparatuses for vehicles, and the like. Ultraviolet semiconductor light emitting devices may be used for various purposes, such as for sterilizing and disinfecting devices, UV curing devices and the like.

### SUMMARY

An aspect of example embodiments of the present inventive concepts is to provide a method of manufacturing a semiconductor light emitting device having improved optical characteristics.

According to an example embodiment of the present inventive concepts, a method of manufacturing a semiconductor light emitting device includes: forming a buffer layer on a substrate; forming a protective layer on the buffer layer; performing a heat treatment on a stacked structure of the substrate, the buffer layer, and the protective layer; removing the protective layer after the heat treatment; and forming a light emitting structure on the buffer layer after removing the protective layer.

According to an example embodiment of the present inventive concepts, a method of manufacturing a semiconductor light emitting device includes: forming a buffer layer having a composition of AlₓGa₁₋ₓN on a substrate, where 0<x≤1; forming a protective layer on the buffer layer such that the protective layer is formed of an dielectric material; performing a heat treatment on the buffer layer after forming the protective layer; and removing the protective layer.

According to an example embodiment of the present inventive concepts, a method of manufacturing a semiconductor light emitting device includes: forming a buffer layer on a substrate; forming a protective layer on the buffer layer such that the protective layer is formed of a material different from a material of the buffer layer; and performing heat treatment on the buffer layer after forming the protective layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a flowchart schematically illustrating a method of manufacturing a semiconductor light emitting device according to example embodiments.

FIG. 2A to FIG. 2F are cross-sectional views schematically illustrating main processes of the method of manufacturing a semiconductor light emitting device according to example embodiments.

FIG. 3A and FIG. 3B are optical micrographs for illustrating characteristics of a semiconductor light emitting device according to example embodiments.

FIGS. 4 and 5 are schematic cross-sectional views of semiconductor light emitting devices according to example embodiments.

FIG. 6 is a schematic cross-sectional view of a semiconductor light emitting device according to example embodiments.

### DETAILED DESCRIPTION

Hereinafter, example embodiments of the present inventive concepts will be described with reference to the accompanying drawings.

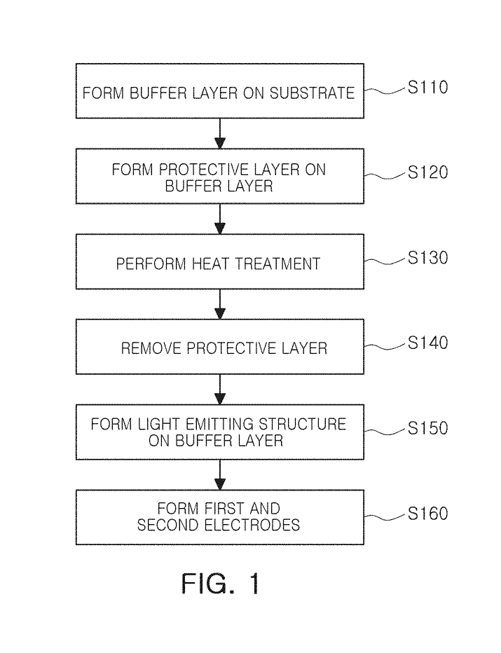

FIG. 1 is a flowchart schematically illustrating a method of manufacturing a semiconductor light emitting device according to example embodiments.

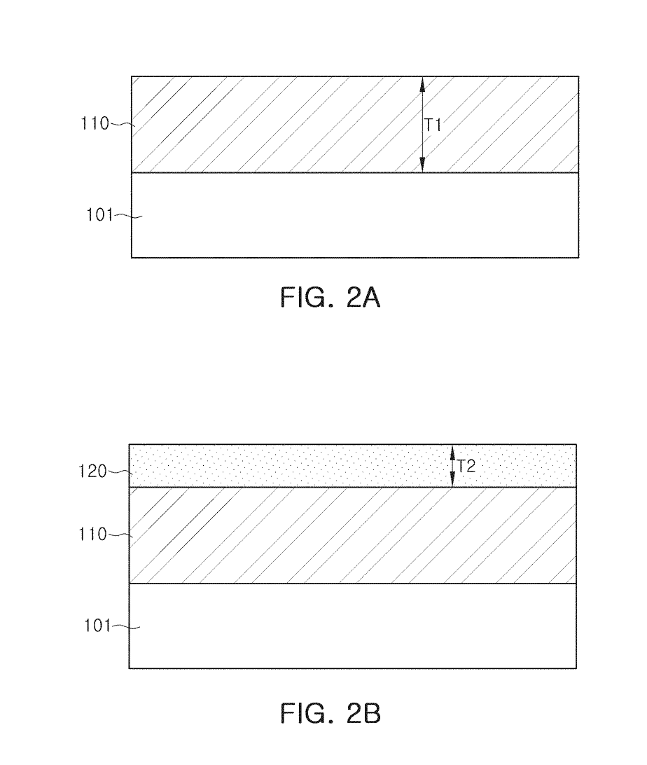

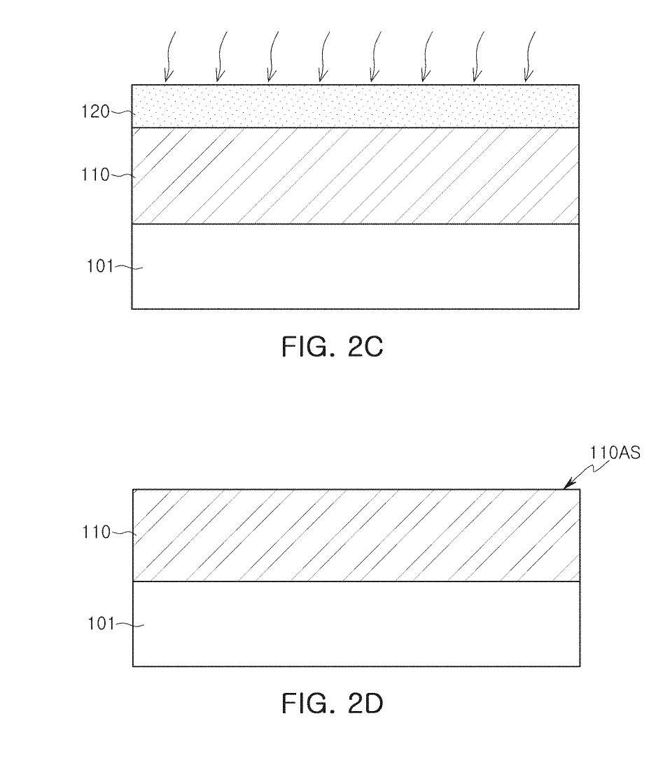

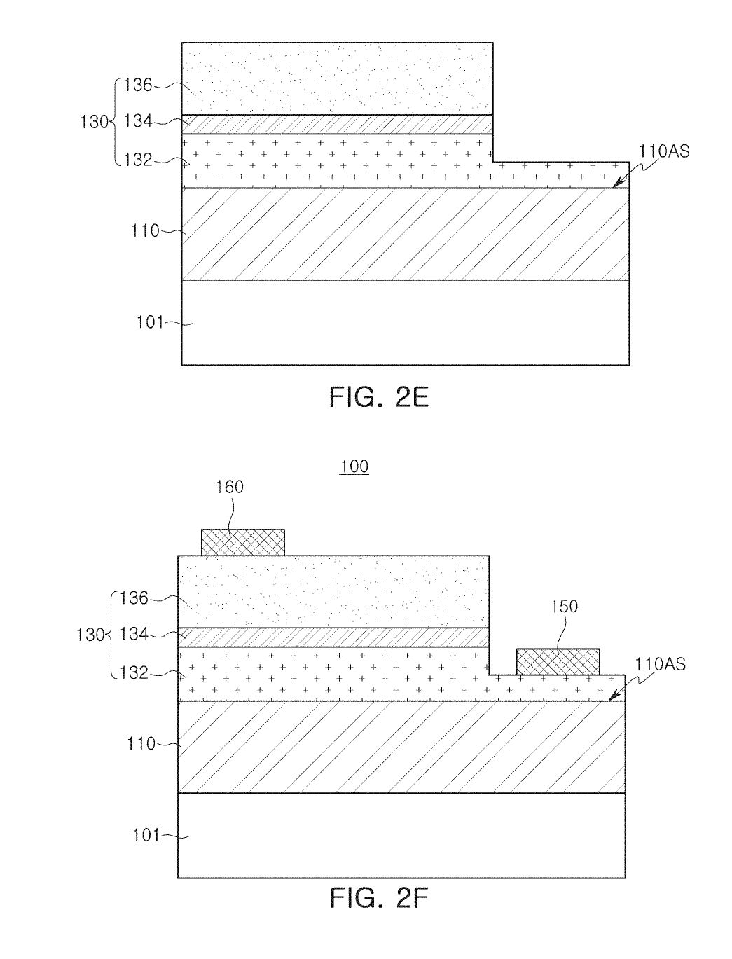

FIG. 2a to FIG. 2f are cross-sectional views schematically illustrating main processes of the method of manufacturing a semiconductor light emitting device according to example embodiments.

Referring to FIG. 1 and FIG. 2a, in operation S110, a buffer layer 110 may be formed on a substrate 101.

The substrate 101 may be a substrate for semiconductor growth, and may be a hetero-substrate for a nitride-based semiconductor layer to be grown thereon. For example, the substrate 101 may be sapphire and in this case, the substrate 101 is stable at high temperatures and may facilitate growth of a nitride film on an upper portion thereof. In addition to such matter, SiC, MgAl₂O₄, MgO, LiAlO₂, LiGaO₂, GaN and the like may be used for the substrate 101.

The buffer layer 110 is a layer for improving crystallinity of semiconductor layers formed thereon. The buffer layer 110 may be formed to reduce crystal defects of the semiconductor layers due to a difference in lattice constants between the substrate 101 and the semiconductor layers. The buffer layer 110 may be formed of, for example, an aluminum gallium nitride (AlₓGa₁₋ₓN, 0<x≤1) grown without doping. For example, when an ultraviolet (UV) semiconductor light emitting device is manufactured, the buffer layer 110 may be MN having relatively high band gap energy.

The buffer layer 110 may be formed on the substrate 101 by a metal organic chemical vapor deposition (MOCVD), hydride vapor phase epitaxy (HYPE), molecular beam epitaxy (MBE), or physical vapor deposition (PVD) process. According to example embodiments, prior to the forming of the buffer layer 110, an internal temperature of a chamber where said process is performed may be raised to a desired (or, alternatively, a predetermined) temperature to allow for desorption of contaminants on the substrate 101.

The buffer layer 110 may be formed to have a first thickness T1, and the first thickness T1 may range from several tens of nanometers to several thousands of nanometers, for example, from 10 nm to 3000 nm. The first thickness T1 may be selected depending on a material of the substrate 101, a thickness and composition of a light emitting structure formed on an upper portion of the buffer layer 110, and the like. In the process, the buffer layer 110 may be amorphous or polycrystalline and may be formed of an epitaxial layer according to a deposition method.

Referring to FIG. 1 and FIG. 2b, in operation S120, a protective layer 120 may be formed on the buffer layer 110.

The protective layer 120 may be a layer for protecting the buffer layer 110 during a subsequent heat treatment process. The protective layer 120 may be formed of a material different from that of the buffer layer 110 or may have a composition different from that of the buffer layer 110. The protective layer 120 may be formed of, for example, a dielectric material. In this case, the protective layer 120 may contain, for example, a silicon oxide (SiO₂), a silicon nitride (SiNₓ), an aluminum oxide (Al₂O₃), a tantalum oxide (Ta₂O₃), a titanium oxide (TiO₂), an yttrium oxide (Y₂O₃), a zirconium oxide (ZrO₂), a hafnium oxide (HfO₂), a lanthanum oxide (La₂O₃), or combinations of these oxides.

The protective layer 120 may be formed by a physical vapor deposition (PVD), chemical vapor deposition (CVD), or atomic layer deposition (ALD) process.

The protective layer 120 may be formed to have a second thickness T2, and the second thickness T2 may range from several angstroms to several hundreds of nanometers, for example, from 5 Å to 1000 Å. When the second thickness T2 is smaller than the above range, protective functions for the buffer layer 110 may not be sufficiently performed. When the second thickness T2 is greater than the above range, process efficiency may be lowered. The second thickness T2 may be smaller than the first thickness T1 of the buffer layer 110, but is not limited thereto, and may be selected depending on heat treatment temperature and time and the like.

Referring to FIG. 1 and FIG. 2c, in operation S130, a heat treatment process may be performed after the protective layer 120 is formed.

The heat treatment process is a process for performing a heat treatment on the buffer layer 110 covered with the protective layer 120. The heat treatment process may be performed to reduce a defect such as dislocation, in the buffer layer 110, thereby improving crystallinity. The heat treatment process may be performed on a stacked structure in which the buffer layer 110 and the protective layer 120 are formed on the substrate 101. The heat treatment process may be performed at a temperature of about 1500° C. to 1800° C. for about 1 hour to 3 hours. The temperature and duration of the heat treatment process may be determined in consideration of temperature and duration at which defects in the buffer layer 110 may be sufficiently reduced. Further, the heat treatment process may be performed within a temperature range in which the stacked structure is not decomposed.

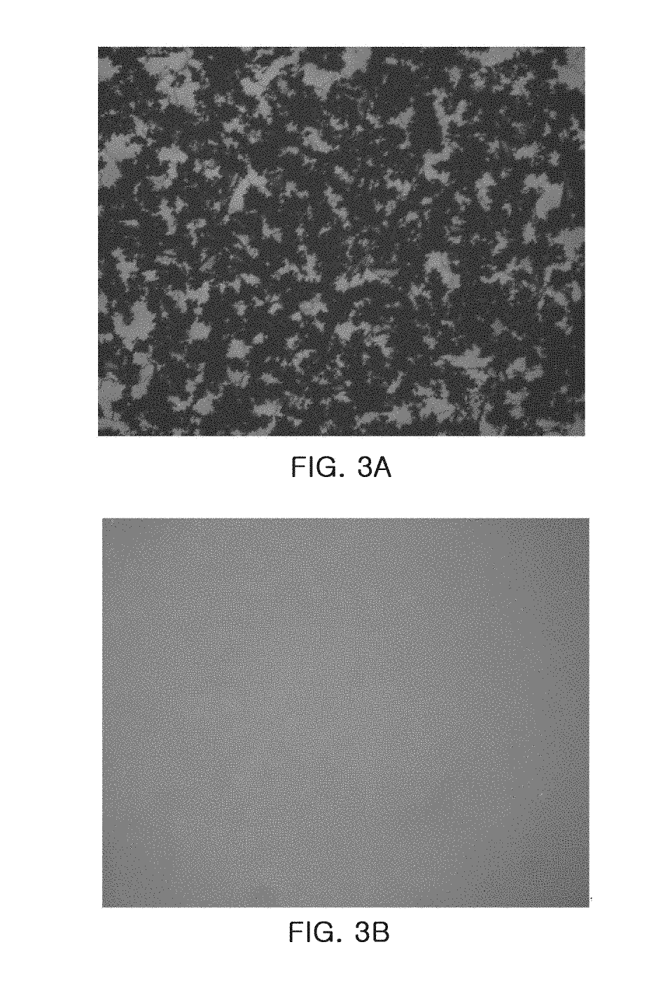

In example embodiments, an upper surface of the buffer layer 110 may be protected by the protective layer 120 during the heat treatment process, and, thus example embodiments may be able to reduce (or, alternatively, prevent) the decomposition of the buffer layer 110 from the upper surface thereof. In the heat treatment process, the buffer layer 110 may be protected from particles or foreign substances adsorbed on a surface thereof. Therefore, when the protective layer 120 is formed and the buffer layer 110 is subjected to heat treatment, particularly, upper surface morphology of the buffer layer 110 may be improved. This will be described in more detail below with reference to FIGS. 3a and 3b.

Referring to FIG. 1 and FIG. 2d, in operation S140, after the heat treatment process is completed, the protective layer 120 may be removed.

The protective layer 120 may be selectively removed from the buffer layer 110 by a dry or wet etching process. An etchant used in the etching process may be selected depending on a material of the protective layer 120 and may be selected as a material that does not affect the surface of the buffer layer 110.

After the protective layer 120 is removed, an upper surface 110AS of the buffer layer 110 covered by the protective layer 120 may be exposed. The upper surface 110AS of the buffer layer 110 may have smooth surface morphology.

Referring to FIG. 1 and FIG. 2e, in operation S150, a light emitting structure 130 may be formed on the buffer layer 110.

The light emitting structure 130 may include a first conductive-type semiconductor layer 132, an active layer 134, and a second conductive-type semiconductor layer 136 sequentially formed on the buffer layer 110. After the light emitting structure 130 is formed, the active layer 134, the second conductivity-type semiconductor layer 136, and the first conductivity-type semiconductor layer 132 are partially removed, as shown in FIG. 2e, such that a portion of the first conductivity-type semiconductor layer 132 may be exposed.

The first and second conductivity-type semiconductor layers 132 and 136 may be formed of semiconductors doped with n-type impurities and p-type impurities, respectively, but are not limited thereto. The first and second conductivity-type semiconductor layers 132 and 136 are formed of a nitride semiconductor, for example, a material having a composition of AlₓIn_{y}Ga_{1-x-y}N (0≤x≤1, 0≤y≤1, 0≤x+y≤1), and each of the layers may be a single layer, but may have a plurality of layers having different characteristics in terms of a doping concentration, a composition, and the like. However, in addition to the nitride semiconductor, AlInGaP or AlInGaAs-based semiconductors may be used for the first and second conductivity-type semiconductor layers 132 and 136.

The active layer 134 is disposed between the first and second conductivity-type semiconductor layers 132 and 136 and may emit light having a desired (or, alternatively, a predetermined) energy through the recombination of electrons and holes. The active layer 134 may be a layer formed of a single material, but may be a single quantum well (SQW) structure or multiple quantum well (MQW) structure in which a quantum well layer and a quantum barrier layer formed by controlling the magnitude of band gap energy while changing the composition of AlₓIn_{y}Ga_{1-x-y}N (0≤x≤1, 0≤y≤1, 0≤x+y≤1) are alternately stacked. For example, a structure of AlGaN/AlGaN, AlGaN/AlN, InGaN/GaN, InGaN/InGaN, InGaN/AlGaN, InGaN/InAlGaN, or GaN/InGaN may be used. In particular, when the active layer 134 emits UV-C (200 to 280 nm wavelength) ultraviolet light, the quantum well layer and the quantum barrier layer may be formed of AlₓGa₁₋ₓN (0.4≤x≤1) having a high Al composition of 40% or more.

Referring to FIG. 1 and FIG. 2f, in operation S160, first and second electrodes 150 and 160 may be formed on the light emitting structure 130.

The first and second electrodes 150 and 160 may be disposed on and electrically connected to the first and second conductive type semiconductor layers 132 and 136, respectively. The first and second electrodes 150 and 160 may be formed of a single layer or multilayer structure of a conductive material.

For example, the first and second electrodes 150 and 160 may contain a material such as aurum (Au), silver (Ag), copper (Cu), zinc (Zn), aluminum (Al), indium (In), titanium (Ti), silicon (Si), germanium (Ge), tin (Sn), magnesium (Mg), tantalum (Ta), chrome (Cr), tungsten (W), ruthenium (Ru), rhodium (Rh), iridium (Ir), nickel (Ni), palladium (Pd), platinum (Pt), or the like, or at least one of alloys of these materials. In example embodiments, at least one of the first and second electrodes 150 and 160 may be a transparent electrode, for example, an ITO (Indium tin Oxide), an AZO (Aluminum Zinc Oxide), an ITO (Indium Zinc Oxide), a zinc oxide (ZnO), GZO (ZnO:Ga), an indium oxide (In₂O₃), a tin oxide (SnO₂), a cadmium oxide (CdO), a cadmium tin oxide (CdSnO₄), or a gallium oxide (Ga₂O₃).

Positions and shapes of the first and second electrodes 150 and 160 shown in FIG. 2f are merely examples, and may be variously changed according to embodiments. In example embodiments, an ohmic electrode layer may be further disposed on the second conductivity-type semiconductor layer 136, and the ohmic electrode layer may include, for example, p-GaN containing a high concentration p-type impurity. Alternatively, the ohmic electrode layer may be formed of a metal material or a transparent conductive oxide.

By the process, finally, a semiconductor light emitting device 100 may be manufactured. In the semiconductor light emitting device 100, since the buffer layer 110 is formed to have a surface such as a mirror surface, with improved crystallinity, through the processes described above, the semiconductor layers constituting the light emitting structure 130 formed on the buffer layer 110 may be formed of films having excellent crystallinity. Therefore, the semiconductor light emitting device 100 may have high output characteristics and improved reliability.

In some example embodiments, the method may further include incorporating the semiconductor light emitting device into an apparatus.

In some example embodiments, the apparatus may be a purifier. For example, the apparatus may be a purifier that is configured to sterilize a substance (e.g., water) using the ultraviolet rays from the semiconductor light emitting device 100. The purifier according to example embodiments may be higher in intensity of ultraviolet rays and purifying ability due to the high output characteristics achieved by the improved buffer layer 110.

In other example embodiments, the apparatus may be a sterilizing device. The sterilizing device according to example embodiments may promote healing and prevent suppuration due to infection and infectious bacteria by preventing the propagation of infectious bacteria using ultraviolet rays from the semiconductor light emitting device 100. The sterilizing device according to example embodiments may be higher in intensity of ultraviolet rays and sterilizing ability due to the high output characteristics achieved by the improved buffer layer 110.

In still other example embodiments, the apparatus may be a curing device. The curing device according to example embodiments may cure a UV sensitive material, such as an ink, adhesive or coating. The curing device according to example embodiments may be higher in intensity of ultraviolet rays and curing ability due to the high output characteristics achieved by the improved buffer layer 110.

FIG. 3A and FIG. 3B are optical micrographs for illustrating characteristics of a semiconductor light emitting device according to example embodiments.

Referring to FIG. 3A and FIG. 3B, there are provided as images showing surfaces of buffer layers after the heat treatment operation (S130) in a comparative example and example embodiments, the images being captured by optical microscopy.

FIG. 3A shows the surface of the buffer layer when a heat treatment was performed without the process of forming the protective layer of operation S120 for the Comparative Example. That is, it is an image of a case in which a heat treatment was performed without the protective layer. FIG. 3B shows the surface of the buffer layer when the protective layer was formed and then, the heat treatment process was performed and the protective layer was removed, as in the processes described above with reference to FIG. 1 to FIG. 2d.

As illustrated in FIG. 3A, in the case of the comparative example, it may be confirmed that the surface of the buffer layer was partially decomposed and detached, whereby a state of the surface was not smooth and roughness thereof was significantly large. On the other hand, as shown in FIG. 3B, in example embodiments, a foreign substance was not present and a smooth surface was exhibited. Therefore, it can be understood that when heat treatment is performed on the buffer layer after the protective layer is formed, the surface state of the buffer layer is improved, and crystal quality of the semiconductor layers forming the light emitting structure formed on the buffer layer may be improved.

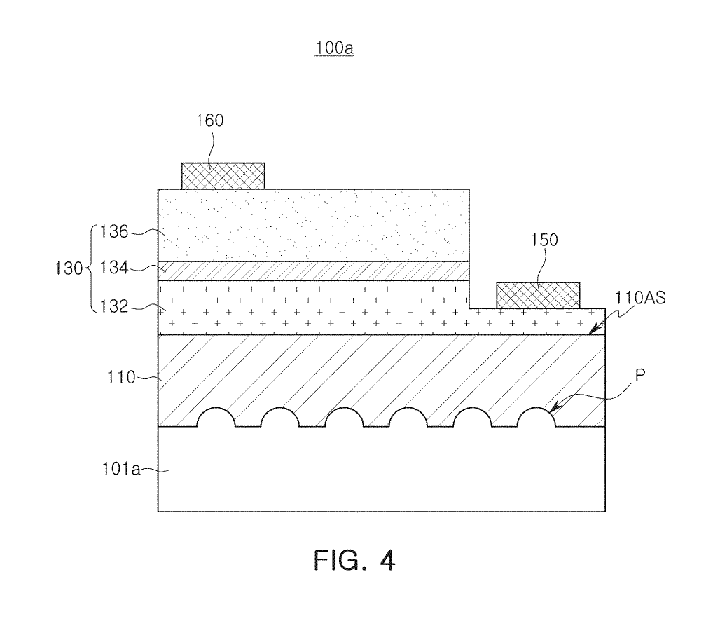

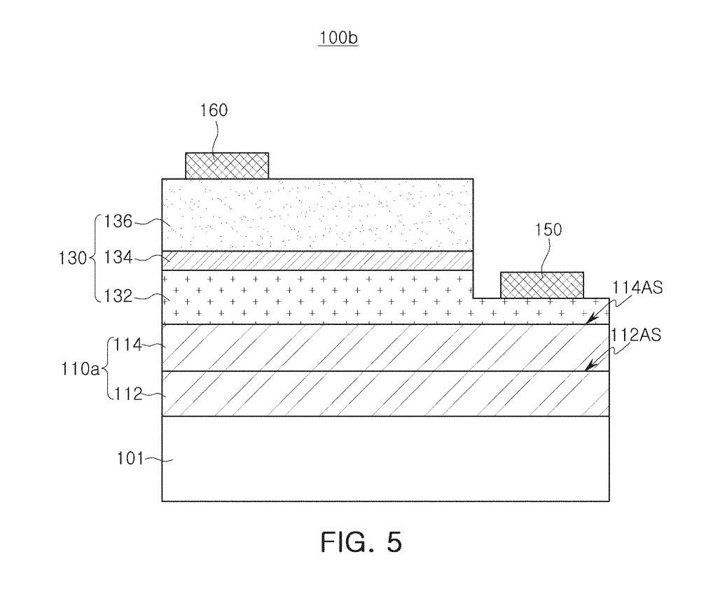

FIGS. 4 and 5 are schematic cross-sectional views of semiconductor light emitting devices according to example embodiments.

Referring to FIG. 4, a semiconductor light emitting device 100a may include a substrate 101a, and a buffer layer 110, a first conductivity-type semiconductor layer 132, an active layer 134, and a second conductivity-type semiconductor layer 136 that are disposed on the substrate 101a. The semiconductor light emitting device 100a may further include the first and second electrodes 150 and 160 as electrode structures.

Unlike the embodiment of FIG. 2f, the semiconductor light emitting device 100a may have a structure in which uneven portions P are formed on an upper surface of the substrate 101a, that is, a growth surface of the semiconductor layers forming the light emitting structure 130. Due to the uneven portions P, crystallinity and light emission efficiency of the semiconductor layers constituting the light emitting structure 130 may be further improved, and light extraction efficiency may be improved.

The semiconductor light emitting device 100a may be manufactured by the manufacturing method described above with reference to FIG. 1 to FIG. 2f. Thus, the buffer layer 110 may have high crystallinity and may have a smooth upper surface 110AS.

Referring to FIG. 5, in a semiconductor light emitting device 100b, a buffer layer 110a may be formed of first and second buffer layers 112 and 114, unlike the example embodiment of FIG. 2f.

The semiconductor light emitting device 100a may be manufactured by the manufacturing method described above with reference to FIG. 1 to FIG. 2f. Specifically, the semiconductor light emitting device 100b may be manufactured by, after forming the protective layer 120 on an upper portion of the first and second buffer layers 112 and 114, performing a heat treatment thereon and then, removing the protective layer 120, during the formation of the respective first and second buffer layers 112 and 114. Thus, the first and second buffer layers 112 and 114 may have high crystallinity and may have smooth upper surfaces 112AS and 114AS. In the example embodiments, the formation of the protective layer 120 and heat treatment processes may be applied to the formation of only one of the first and second buffer layers 112 and 114. For example, the protective layer 120 may be formed and thermally treated only when the second buffer layer 114 in direct-contact with the light-emitting structure 130 is formed. This can be determined according to the purpose of forming the first and second buffer layers 112 and 114, materials thereof, and the like.

The buffer layer 110a is formed to have a structure including the first and second buffer layers 112 and 114, thereby further improving film quality of the light emitting structure 130 formed thereon. For example, by further forming the second buffer layer 114, the progress of defects such as dislocations in the first buffer layer 112 may be interrupted. The second buffer layer 114 may have a composition different from that of the first buffer layer 112. For example, the second buffer layer 114 may have a composition between those of the first buffer layer 112 and the first conductivity-type semiconductor layer 132, and for example, the second buffer layer 114 may have a higher content of aluminum (Al) than the first buffer layer 112.

In example embodiments, a superlattice layer may be further disposed between the buffer layer 110a and the light emitting structure 130. The superlattice layer may be a layer in which a plurality of layers having different levels of band gap energy are alternately, repeatedly stacked, and may include n-type impurities. The superlattice layer forms a two-dimensional electron gas layer at an interface thereof due to discontinuity of energy bands caused by the plurality of layers. Thus, a tunneling phenomenon occurs through the two-dimensional electron gas layer when a voltage is applied, such that cladding effects of the first conductivity-type semiconductor layer 132 disposed above the superlattice layer may be improved, and high carrier mobility may be ensured to improve current diffusion effects. In addition thereto, the semiconductor light emitting device 100b may further include various compositions and numbers of cladding layers.

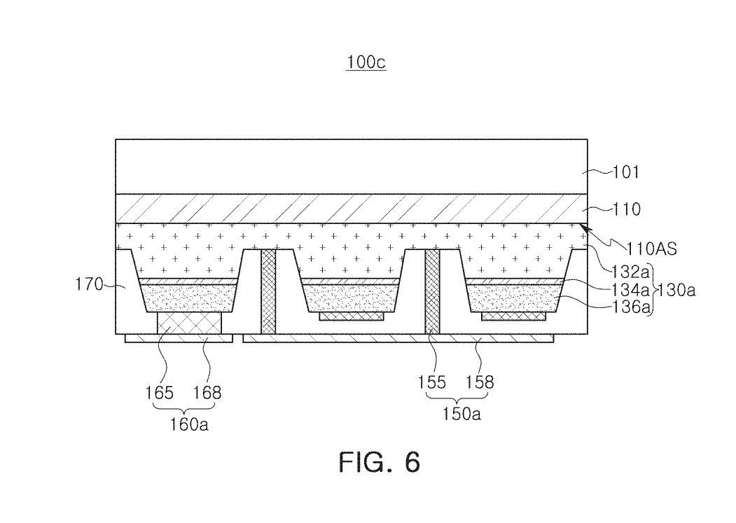

FIG. 6 is a schematic cross-sectional view of a semiconductor light emitting device according to example embodiments.

Referring to FIG. 6, a semiconductor light emitting device 100c may include a light emitting structure 130a having a shape different from that of the embodiment shown in FIG. 2f, and structures of the first and second electrodes 150a and 160a may be different from those of the example embodiment shown in FIG. 2f. The semiconductor light emitting device 100c may further include an insulating part 170. The semiconductor light emitting element 100c may be manufactured by employing the manufacturing method described above with reference to FIG. 1 to FIG. 2f. Thus, the buffer layer 110 may have high crystallinity and may have a smooth upper surface 110AS.

The first electrode 150a may include a connection electrode part 155 in the form of a conductive via that is connected to the first conductivity-type semiconductor layer 132a by penetrating through the second conductivity-type semiconductor layer 136a and the active layer 134a, and a first electrode pad 158 connected to the connection electrode part 155. The connection electrode part 155 may be surrounded by the insulating part 170 and electrically separated from the active layer 134a and the second conductivity-type semiconductor layer 136a. The number, shape and pitch of the connection electrode unit 155, or the contact area of the connection electrode unit 155 with the first conductivity-type semiconductor layer 132a may be appropriately designed so as to lower contact resistance. The second electrode 160a may include an ohmic-contact layer 165 and a second electrode pad 168 on the second conductivity-type semiconductor layer 136a.

The connection electrode part 155 and the ohmic-contact layer 165 may have a single layer or multilayer structure of a conductive material having ohmic characteristics with the first and second conductivity-type semiconductor layers 132a and 136a, respectively. For example, the connection electrode part 155 and the ohmic-contact layer 165 may be formed of at least one of Ag, Al, Ni, Cr and a transparent conductive oxide (TCO).

The first and second electrode pads 158 and 168 may be connected to the connection electrode part 155 and the ohmic-contact layer 165, respectively, to function as external terminals of the semiconductor light emitting device 100c. For example, the first and second electrode pads 158 and 168 may contain Au, Ag, Al, Ti, W, Cu, Sn, Ni, Pt, Cr, NiSn, TiW, AuSn, or eutectic metals thereof. The first and second electrodes 150a and 160a may be arranged in the same direction, and may be mounted on a lead frame or the like, in flip chip form.

The first and second electrodes 150a and 160a may be electrically separated from each other by the insulating part 170. The insulating part 170 may be formed of an insulating material, and a material having low light absorptivity may be used. For example, for the insulating part 170, a silicon oxide or silicon nitride such as SiO₂, SiOₓN_{y}, SiₓN_{y} or the like may be used. In one embodiment, the insulating part 170 may be formed as a light reflecting structure in which light reflective fillers are dispersed in a light-transmitting material. Alternatively, the insulating part 170 may be a multilayer reflective structure in which a plurality of insulating layers having different refractive indices are alternately stacked.

As set forth above, a method of manufacturing a semiconductor light emitting device having improved optical characteristics by covering the protective layer and performing heat treatment on the buffer layer can be provided.

Various and advantageous advantages and effects of example embodiments of the present inventive concepts are not limited to the above descriptions, and can be more easily understood in describing example embodiments of the present inventive concepts.

While example embodiments have been shown and described above, it will be apparent to those skilled in the art that modifications and variations could be made without departing from the scope of the present inventive concepts as defined by the appended claims.

What is claimed is:

1. A method of manufacturing a semiconductor light emitting device, the method comprising:
forming a buffer layer on a substrate;
forming a protective layer on the buffer layer;
performing a heat treatment on a stacked structure of the substrate, the buffer layer, and the protective layer;
removing the protective layer after the heat treatment; and
forming a light emitting structure on the buffer layer after removing the protective layer.

2. The method of claim 1, wherein the forming the protective layer forms the protective layer such that the protective layer is formed of a dielectric material.

3. The method of claim 2, wherein the forming the protective layer forms the protective layer such that the protective layer includes at least one of a silicon oxide, a silicon nitride and an aluminum oxide.

4. The method of claim 1, wherein the performing the heat treatment includes inhibiting surface decomposition of the buffer layer by the protective layer during the heat treatment.

5. The method of claim 1, wherein the performing the heat treatment performs the heat treatment at a temperature of between 1500° C. to 1800° C.

6. The method of claim 1, wherein the performing the heat treatment performs the heat treatment for between 1 to 3 hours.

7. The method of claim 1, wherein the forming the protective layer forms the protective layer such that the protective layer has a thickness of 5 Å to 1000 Å.

8. The method of claim 1, wherein the forming the buffer layer forms the buffer layer such that the buffer layer has a composition of AlₓGa₁₋ₓN, wherein 0<x≤1.

9. The method of claim 1, wherein the forming the buffer layer forms the buffer layer such that the buffer layer has a thickness of 10 nm to 3000 nm.

10. The method of claim 1, wherein, in the forming of the buffer layer, the buffer layer is formed in polycrystalline.

11. The method of claim 1, wherein the forming the light emitting structure forms the light emitting structure such that the light emitting structure includes a first conductivity-type semiconductor layer, an active layer, and a second conductivity-type semiconductor layer, sequentially stacked on the buffer layer.

12. The method of claim 11, wherein the active layer includes a layer having a composition of AlₓGa₁₋ₓN (0.4≤x≤1).

13. The method of claim 11, further comprising:
forming first and second electrodes connected to the first conductivity-type semiconductor layer and the second conductivity-type semiconductor layer, respectively.

14. The method of claim 1, further comprising:
forming an additional buffer layer on the buffer layer after the removing of the protective layer.

15. The method of claim 14, wherein the forming the additional buffer layer forms the additional buffer layer such that the additional buffer layer has a higher content of aluminum (Al) than the buffer layer.

16. A method of manufacturing a semiconductor light emitting device, the method comprising:
forming a buffer layer having a composition of AlₓGa₁₋ₓN on a substrate, where 0<x≤1;
forming a protective layer on the buffer layer such that the protective layer is formed of an dielectric material;
performing a heat treatment on the buffer layer after forming the protective layer; and
removing the protective layer.

17. The method of claim 16, wherein the performing the heat treatment performs the heat treatment at a temperature of about 1500° C. to 1800° C.

18. The method of claim 16, wherein the buffer layer is Aluminum nitride (AlN).

19. The method of claim 16, wherein the substrate is a sapphire substrate.

20. A method of manufacturing a semiconductor light emitting device, the method comprising:
forming a buffer layer on a substrate;
forming a protective layer on the buffer layer such that the protective layer is formed of a material different from a material of the buffer layer; and
performing heat treatment on the buffer layer after forming the protective layer.
